(19) United States
(12) Patent Application Publication
(10) Pub. No.: US 2007/0101211 A1
(43) Pub. Date: May 3, 2007

(54) Defect management method and disk drive using the same

(75) Inventors: Chun-ying Chiang, Chiayi City (TW); Yih-shin Weng, Jhubei City (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: MediaTek Inc.

(21) Appl. No.: 11/412,428

(22) Filed: Apr. 27, 2006

Related U.S. Application Data
(60) Provisional application No. 60/732,844, filed on Nov. 2, 2005.

(51) Int. Cl. G11C 29/00

(52) U.S. Cl. 714/710

(57) ABSTRACT

A method and device for management of defects in a recording medium such as a DVD disc are disclosed. The present invention utilizes defect processing table to reduce the seek times of a pick-up head in obtaining replacement ECC blocks for defect ECC blocks in a user data area of the disc. The defect processing table is used to indicate a location to access replacement block for a defect block. Since the defect processing table (DPT) stores only the relevant information about the defect block and replacement block rather than the defect block or the replacement block per se, it only needs a very small memory space. The present invention also provides a DPT management unit to manage the contents of the DPT.

This application claims priority to and incorporates by reference the disclosure set forth, in its entirety, in U.S. Provisional Patent Application No. 60/732,844, entitled “DETECT MANAGEMENT METHOD OF USING DEFECT PROCESSING TABLE” filed on Nov. 2, 2005.

### TECHNICAL FIELD OF THE INVENTION

The present application relates to management of defects in a recording medium such as an optical disc, more particularly, to a method for managing defects of the optical disc with a defect processing table, and a disc drive having the defect processing table.

### BACKGROUND OF THE INVENTION

Generally, an optical disc 10 (e.g. a DVDRAM disc) is divided into a lead-in area (LIA) 11, a user data area 13 and a lead-out area (LOA) 15. In addition, there is a primary spare area (PSA) 17 in front of the user data area 13 and a secondary spare area (SSA) 19 optionally provided in back of the user data area 13, as shown in FIG. 1.

For a registered defect (e.g. a defect ECC block) in the user data area, a replacement (e.g. a replacement ECC block) is recorded in the spare area. In the example of FIG. 1, there are three defect ECC blocks 101, 103, 105 in the user data area 13. Replacement ECC blocks 111, 113, 115 corresponding to the defect ECC blocks 101, 103, 105 are recorded in the primary spare area 17 as shown.

When writing the optical disc 10, a pick-up head writes a first section of the user data area and stops writing when the first defect ECC block 101 is recoreded, this course is indicated as Rec. 1 in FIG. 1. Then the pick-up head jumps to write the replacement ECC block 111 to replace the defect ECC block 101, this course is indicated as Rec. 2. The pick-up head successively writes a second section of the user data area 13 after the first defect ECC block 101, and stops writing when the second defect ECC block 103 is recorded, this course is indicated as Rec. 3. The pick-up head then jumps to write the replacement ECC block 113 to replace the defect ECC block 103, this course is indicated as Rec. 4. The pick-up head successively writes a third section of the user data area 13 after the second defect ECC block 103, and stops writing when the third defect ECC block 105 is recorded, this course is indicated as Rec. 5. The pick-up head jumps to write the replacement ECC block 115 to replace the defect ECC block 105, this course is indicated as Rec. 6.

As described above and as shown in FIG. 1, the pick-up head needs to move back and forth to write the good information in the user data area and the replacement ECC blocks. A method for reducing the number of seek times of the pick-up head is to provide a buffer memory 20, as shown in FIG. 2. In a writing operation, for example, rather than writing the replacement ECC block whenever a defect ECC block is recorded, the write defect ECC block is temporarily stored the buffer memory. After the writing operation is completed, the replacement ECC blocks corresponding to the stored defect ECC blocks are collectively write. However, such a method requires a considerable capacity of memory.

The present invention provide a solution to overcome the drawbacks mentioned above.

### SUMMERY OF THE INVENTION

An objective of the present invention is to provide a method for management of defects in a recording medium such as a DVD disc. The method of the present invention utilizes defect processing table, which occupies a small memory space, to reduce the seek times of a pick-up head in obtaining replacement ECC blocks for defect ECC blocks in a user data area of the disc.

Another object of the present invention is to provide a defect processing table, which is disposed in a computer readable medium, such as a buffer. The defect processing table is used to indicate a location to access replacement for a defect. For a reading or writing operation, relevant information about all defects found in the user data area and the corresponding replacements is appended into the defect processing table, so that the replacements for the defects can be obtained collectively. Since the defect processing table (DPT) stores only the relevant information about the defects and replacements rather than the defects or the replacements, it only needs a very small memory space. The present invention also provides a DPT management unit to manage the contents of the DPT. The DPT has a plural of items, each of which includes defect related information of one defect. In an embodiment, the DPT has a plurality of rows, and one item is disposed in one row. The defect related information includes information indicating the defect location, information indicating the replacement location, and defect index indicating a location of which the defect is stored in memory.

A further objective of the present invention is to provide an optical disc drive comprising the computer readable medium with the DPT and the management unit. an apparatus having the DPT and the DPT management unit mentioned above.

### BRIEF DESCRIPTION OF THE DRAWINGS

The present invention will be further described in detail in conjunction with the accompanying drawings, wherein:

FIG. 1 schematically shows a general structure of an optical disc;

FIG. 2 schematically shows a prior art method for processing defects of the optical disc in FIG. 1;

FIG. 3 schematically shows a method for process defects of the optical disc in accordance with the present invention;

FIG. 4 is a block diagram schematically and generally showing a disc drive in accordance with the present invention;

FIG. 5 is a schematic and general illustration of a defect processing table in accordance with the present invention;

FIG. 6 schematically shows a structure of an optical disc, in which defect and replacement blocks are processed by the method in accordance with the present invention in a reading operation;

FIGS. 7A to 7E show an embodiment of the defect processing procedure in accordance with the present invention in a reading operation;

FIG. 8 schematically shows a structure of an optical disc, in which defect and replacement blocks are processed by the method in accordance with the present invention in a writing operation;

FIGS. 9A to 9F show an embodiment of the defect processing procedure in accordance with the present invention in a writing operation;

### DETAILED DESCRIPTION OF THE INVENTION

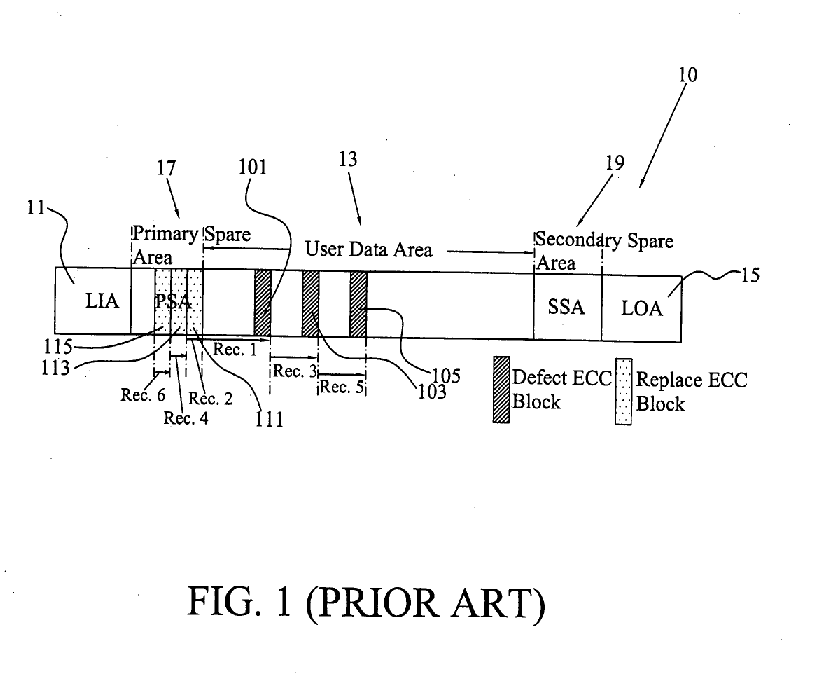

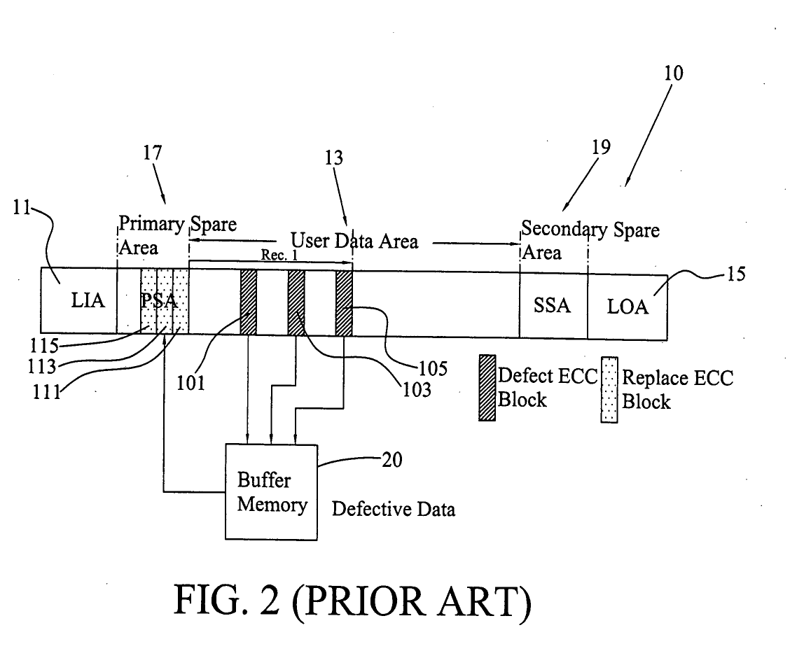

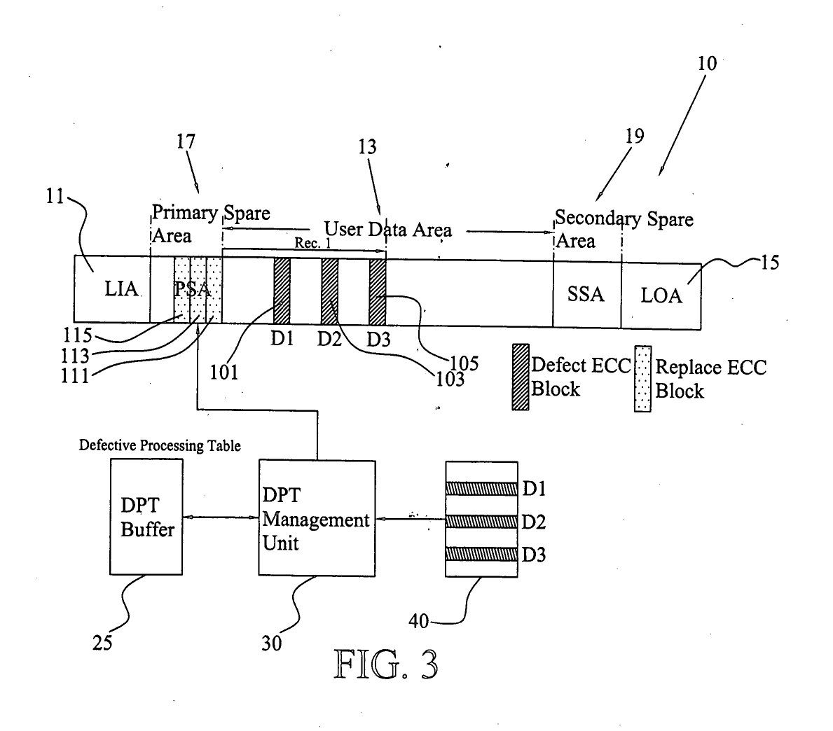

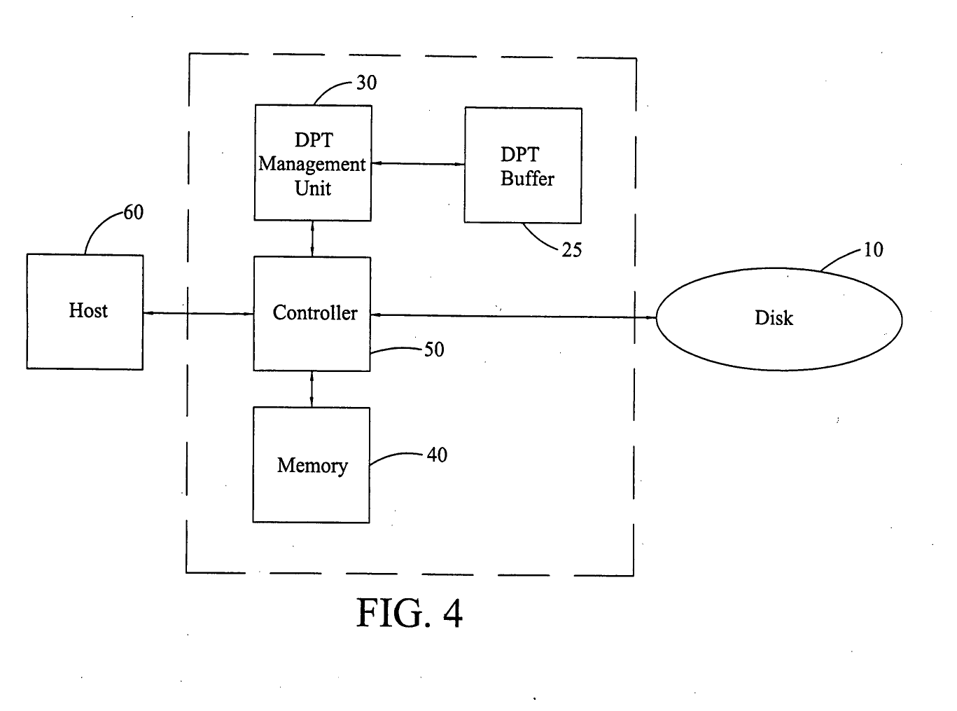

Referring to FIGS. 3 and 4, wherein FIG. 3 schematically shows a method for process defects of the optical disc in accordance with the present invention, and FIG. 4 is a block diagram schematically and generally showing a disc drive in accordance with the present invention. In FIG. 3, the optical disc structure as shown is the same as that of FIG. 1 or FIG. 2, and the same reference numbers indicates the same portions.

As shown in FIGS. 3 and 4, to manage defects of the optical disc 10 with a quite limited memory capacity, a disc drive in accordance with the present invention has a defect processing table (DPT) buffer 25, in which a defect process table (DPT) is disposed. The DPT can also disposed in any other computer readable medium. The DPT contains defect related information about a defect rather than the practical content thereof. The details about the DPT will be further described later. The present invention also provides a DPT management unit 30 to manage the DPT stored in the DPT buffer 25. The DPT buffer 25 and the DPT management unit 30 can be considered together as a defect management device. The DPT management unit 30 may directly access a memory 40 or access the memory 40 via a controller 50, which is coupled with a host 60 and accesses the optical disc 10. As currently conventional practice, defects such as defect blocks are stored in the memory 40. It is noted that the DPT buffer 25 can be implemented by and individual memory or just a portion of the memory 40.

In the example of FIG. 3, during a first recording operation Rec. 1, three defect blocks 101, 103, 105 are found. The defect related information about these three defect blocks are recorded in the DPT of the DPT buffer 25. The DPT management unit 30 obtains the replacement blocks 111, 113, 115, and replaces the defect blocks 101, 103, 105 with the replacement blocks by accessing the defect blocks and replacement blocks according to the defect related information recorded in the DPT.

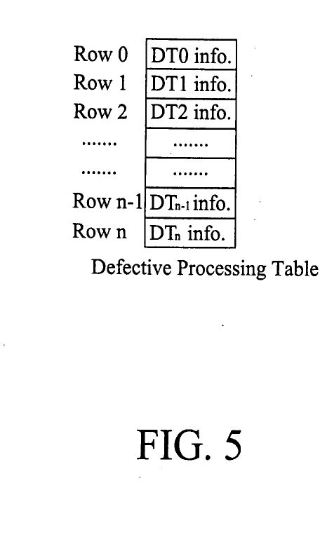

FIG. 5 is a schematic and general illustration of the defect processing table (DPT) in accordance with the present invention. As shown, the DPT has a plurality of rows, n+1 rows in this example. The defect related information for one defect in the optical disc 10, which is referred to as one item, is appended into one row of the DPT. That is, the defect related information items of defects DT0 to DTn are respectively recorded in Row 0 to Row n of the DPT. The defect related information at least contains necessary information about the defect. The DPT management unit 30 uses the information recorded in the DPT to process the defect.

In the present embodiment, the defect related information includes information for indicating a location to access a defect on the optical disc 10, information for indicating a location to access a replacement for the defect and information for indicating a location to access the defect stored in the memory 40. Preferably, the information for indicating a location to access a defect on the optical disc 10 is a defect address, such as defect TLSN value in a reading operation or defect PID value is a writing operation; the information for indicating a location to access a replacement for the defect is a replacement address, such as a replacement PID value; and information for indicating a location to access the defect stored in the memory 40 is a defect index indicating the location of the memory 40 where the defect content is stored. In this case, each row of the DPT only requires 8 bytes, wherein three bytes are used to record the defect address, another three bytes are used to record the replacement address and two bytes are used to record the defect index. Therefore, in general, a memory space of hundreds of bytes is sufficient. In comparison, the prior art, in which the defect blocks are stored in the buffer directly, requires a considerably large memory space, since one defect ECC block occupies 32 k bytes for DVD disc in practice.

In the above description, the addresses of the defects and replacements are recorded in the DPT. However, the form of the information to be recorded in the DPT is not limited to this. For example, the relative relationship between the defects or replacements rather than the addresses thereof can be recorded. Furthermore, additional information can also be recorded into the DPT as desired.

The processes of the DPT management unit 30 managing the DPT in reading and writing operations for the optical disc 10 will be respectively described.

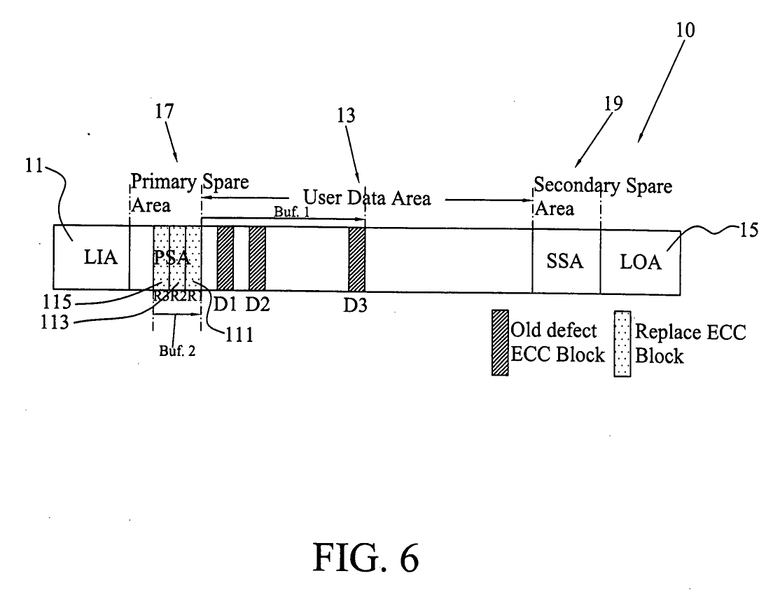

FIG. 6 schematically shows a structure of the optical disc 10, in which defect and replacement blocks are processed by the method in accordance with the present invention in a reading operation. The structure shown in this drawing is substantially the same as that shown in FIG. 1 or FIG. 2. The same reference numbers indicate the same portions in these drawings. After reading the user data area 13 of the optical disc 10 (the period indicated by Buf. 1), defect blocks 101, 103, 105 located at locations with the addresses D1, D2, D3 are found, and the replacement blocks 111, 113, 115 are recorded at the locations in the primary spare area 17 with the addresses R1, R2, R3. The DPT management unit 30 records the addresses of the defect blocks D1,D2, D3, address of the replacement blocks R1, R2, R3 and the defect indices B1, B2, B3 of the defect blocks into the DPT. The details will be further described as follows.

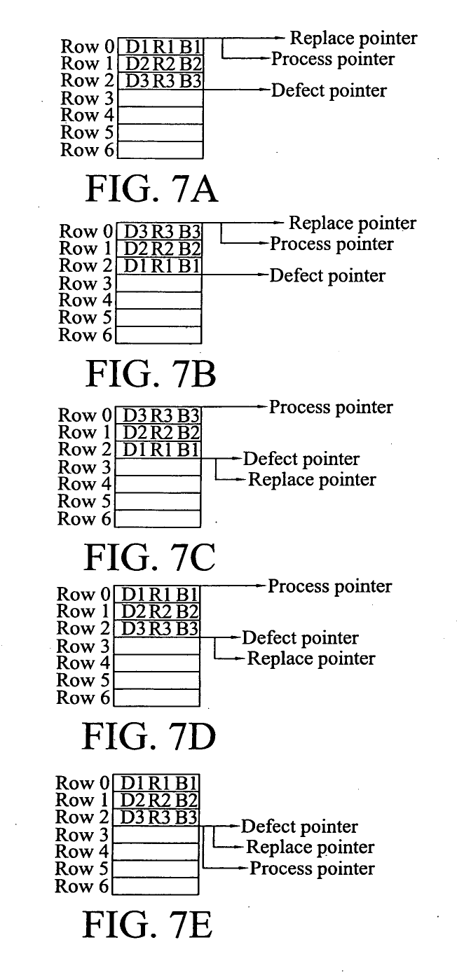

FIGS. 7A to 7E show the respective steps of the defect processing procedure in accordance with an embodiment of the present invention in a reading operation. During reading, the DPT management unit 30 uses three pointers to manage the DPT, in which the defect related information such as defect address, replace address and defect index for each defect is stored in a row. The three pointers are defect pointer, replace pointer and process pointer. For reading operation, the defect pointer indicates that a reading of a defect block is finished; the replace pointer indicates that a reading of a replacement block is finished; the process pointer indicates that the transfer of the replacement block is done.

As shown in FIG. 7A, after reading the defect blocks 101, 103, 105, (Buf. 1 in FIG. 6), the DPT management unit 30 records the addresses of the defect blocks, replacement blocks and the defect indices to the DPT. The defect address D1 of the first defect block 101, replacement address R1 of the replacement block 111 and the defect index B1 for the first defect block are recorded in the first low, Row 0, of the DPT. The defect address D2 of the second defect block 103, replacement address R2 of the replacement block 113 and the defect index B2 for the second defect block are, recorded in Row 1 of the DPT. The defect address D3 of the third defect block 105, replacement address R3 of the replacement block 115 and the defect index B3 for the third defect block are recorded in Row 2 of the DPT. At this time, since the defect blocks 101, 103, 105 have been read, the defect pointer points to Row 3 of the DPT. The replace pointer and the process pointer both point to Row 0 of the DPT.

The sequence of recording the replacement blocks is from outer side to inner side, while the direction of reading is from inner side to outer side. Before reading the replacement blocks, the DPT management unit 30 conducts a sorting to the rows of the DPT according to the reading order for the replacement blocks, that is R3, R2, R1, as shown in FIG. 7B.

After the replacement blocks 111, 113, 115 are read (Buf. 2 period, FIG. 6), the replace pointer points to row 3, as shown in FIG. 7C. The replacement blocks 111, 113, 115 can be read and copied to cover the defect blocks stored in the memory 40 or be read and stored in another memory as desired.

Before transferring the replacement block data, the DPT management unit 30 conducts another sorting to the rows of the DPT according to order of the defect blocks, that is D1, D2, D3, as shown in FIG. 7D.

Whenever data such as the replacement block data for a defect is transferred, the process pointer is added with one. After the three replacement blocks are transferred, the process pointer also points to Row 3, as shown in FIG. 7E. The management for the reading operation is finished.

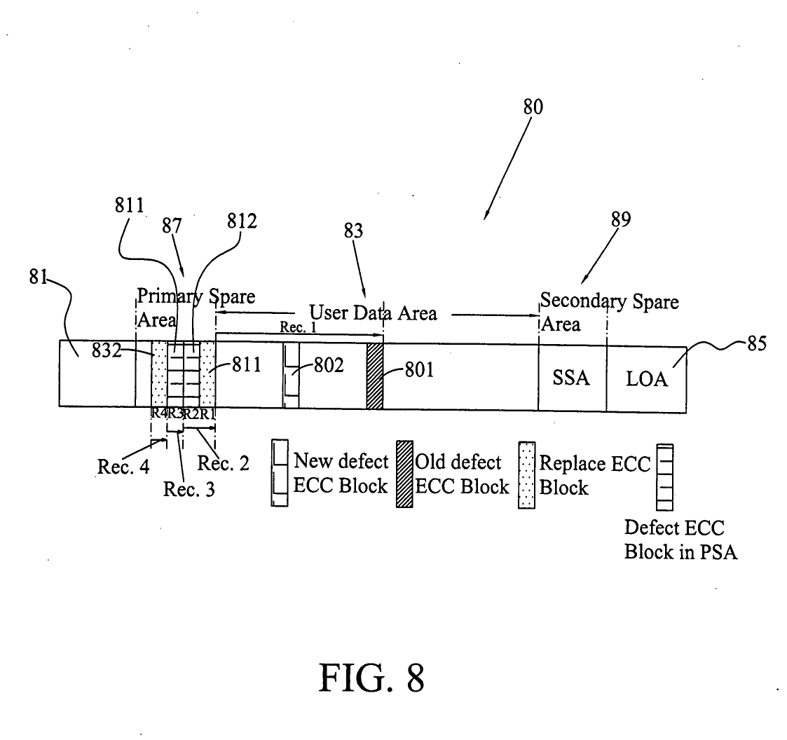

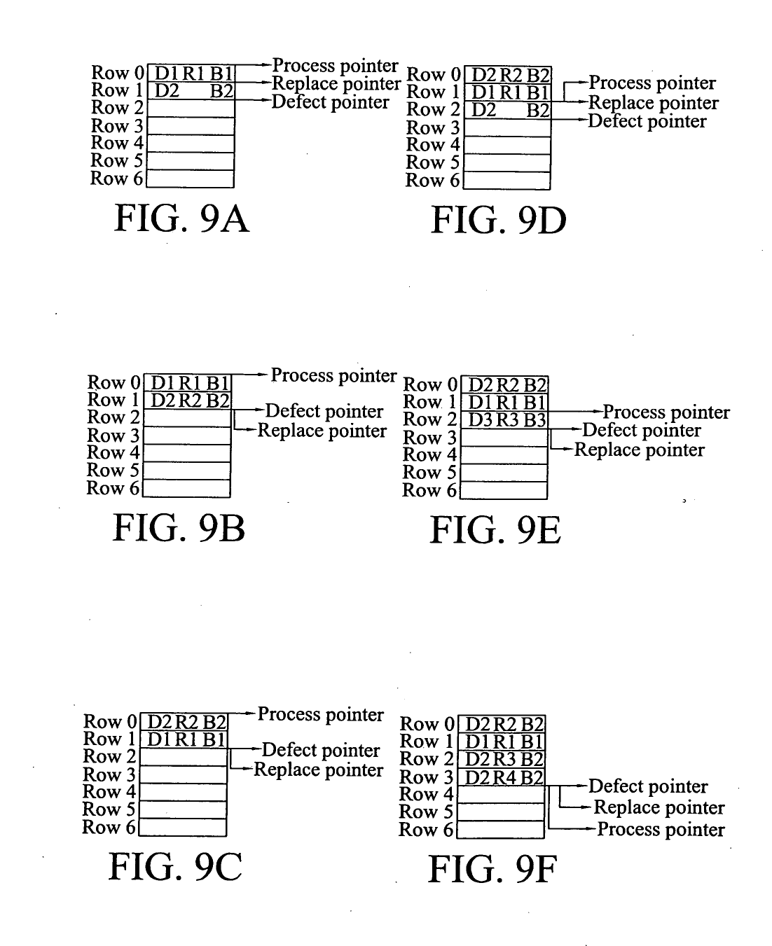

The management of the DPC management unit 30 for a recording operation will be described with reference to FIGS. 8 and 9. During the recording operation, the DPC management unit 30 also uses the three indices, defect pointer, replace pointer and process pointer. However, these indices indicate different meanings as compared to the reading operation. For recording operation, the defect pointer indicates that the writing of a defect block is finished; the replace pointer indicates that the address of the replacement block for the defect block is obtained; the process pointer indicates that the writing of the replacement block is finished.

FIG. 8 shows a structure of an optical disc 80, which is similar to that of the optical disc 10 of FIG. 1. The like reference numbers indicate the similar portions. As shown, the optical disc 80 has a LIA 81, a user data area 83, and a LOA 85. There are a primary spare area 87 and secondary spare area 89 in front and back of the user data area, respectively. In this example, during the writing operation, an old registered defect block 801 is found at a location with an address D1. A replacement block 811 for the defect block 801 is recorded at a location with an address R1 in the primary spare area 87. After the writing operation (Rec. 1) is finished, a new defect block 802 is found at a location with an address D2 in verification for the writing operation. The DPT management unit 30 records the defect addresses D1, D2, the replacement address R1, and defect indices B1, B2, as shown in FIG. 9A. The defect pointer points to Row 2. However, the replace pointer points to Row 1, since an address of a replacement block for the defect block at D2 has not been obtained. The process pointer points at Row 0.

A new replacement block 812 is obtained for the defect block 802 found during the verification. The replacement block 812 is recorded at a location with an address R2 as shown in FIG. 8. The DPT management unit 30 obtains the address R2 of the replacement block 812 and fills it into the DPT, as shown in FIG. 9B. Now the replace pointer also points to Row 2.

Similar to the reading operation, before recording the replacement blocks, the sequence of the rows of the DPT is sorted according to the order that the replacement blocks to be recorded, that is, R2 to R1, as shown in FIG. 9C. The recording of the replacement blocks 811, 812 (Rec. 2, FIG. 8) is that the DPT management unit 30 obtains the original data to be recorded in the defect blocks 801, 802 according to the defect indices B1, B2 and directly writes the original data to the replacement blocks 811, 812. It does not need an additional buffer memory to store the original data.

After the replacement blocks 811, 812 are recorded, the process pointer points to Row 2, a verification is executed. If it is found that replacement block 812 at the address R2 is defective, the DPT management unit 30 fills the original defect address D2 of R2, and the corresponding defect index B2 at a new row (Row 2 in this example) of the DPT, as shown in FIG. 9D. The defect pointer points to Row 3. The replace pointer and the process pointer maintain at Row 2.

The DPT management unit 30 repeats the step described with FIG. 9B to obtain an address R3 of a new replacement block 822, and fills the address R3 into Row 2 of the DPT, as shown in FIG. 9E. At this time, the replace pointer also points to Row 3.

If the replacement block 822 is also defective, the DPT management unit 30 will repeats the steps described above to get an address R4 of a new replacement block 832. As shown in FIG. 9F, the defect related information including the defect block D2, the replacement block address R4 and the defect index B2 is recorded in Row 3 of the DPT. As above, a verification is executed. It there is no additional defective block found, the writing of the replacement blocks is done, and all of the three indices used by the DPT management unit 30 point to the same row, Row 4 in the present embodiment, as shown in FIG. 9F.

As described above, either in the reading or recording operation, when the three pointers of the DPT management unit 30 points to the same row of the DPT, the process of the operation is completed.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A method for managing defects of an optical disc, said method comprising steps of:
appending defect related information about a defect into a defect processing table when the defect is found; and
processing the defect according to the defect related information thereof appended in the defect processing table, the defect processing table having a plurality of items, each item comprising defect related information for one defect.

2. The method of claim 1, wherein the defect related information comprises information for indicating a location to access the defect on the disc.

3. The method of claim 1, wherein the defect related information comprises information for indicating a location of a replacement recorded on the disc, the replacement is to be used for replacing the defect.

4. The method of claim 1, wherein the defect is stored in a memory, and the defect related information comprises information indicating a location of the memory where the defect is stored.

5. The method of claim 1, wherein the processing step comprises accessing the defect, accessing a replacement for the defect, and replacing the defect with the replacement.

6. The method of claim 5, wherein the processing step further comprises sorting the items of the defect processing table for a plurality of defects according to a sequence that the replacements on the disc to be accessed before accessing the replacements.

7. The method of claim 6, wherein the processing step further comprises sorting the items of the defect processing table for the defects according to a sequence that the defects on the disc to be accessed before replacing the defects with the replacements.

8. A computer readable medium for storing information for managing defects of an optical disc, said computer readable medium having a defect processing table with a plurality of items, each item comprising defect related information for one defect.

9. The computer readable medium of claim 8, wherein the defect is to be processed according to the defect related information in the defect processing table.

10. The computer readable medium of claim 8, wherein the defect related information comprises information for indicating a location of the defect on the disc.

11. The computer readable medium of claim 8, wherein the defect related information comprises information for indicating a location of a replacement recorded on the disc, the replacement is to be used to replace the defect.

12. The computer readable medium of claim 8, wherein the defect is stored in a memory, and the defect related information comprises information indicating a location of the memory where the defect is stored.

13. A disc drive for an optical disc, said disc drive comprising:
a computer readable medium having a defect processing table in which defect related information for a defect of the disc is appended;
a memory storing the defect; and
a defect processing table management unit managing the defect by accessing the defect stored in the memory and accessing a replacement recorded on the disc for the defect according to the defect related information in the defect processing table.

14. The disc drive of claim 13, further comprising a controller, wherein the defect processing table management unit accesses to the memory via the controller to obtain the defect stored therein.

15. The disc drive of claim 13, wherein the defect related information comprises information for indicating a location of the defect on the disc.

16. The disc drive of claim 13, wherein the defect related information comprises information for indicating a location of a replacement recorded on the disc, the replacement is to be used for replacing the defect.

17. The disc drive of claim 13, wherein the defect related information comprises information indicating a location of the memory where the defect is stored.

18. The disc drive of claim 13, wherein the defect processing table management unit uses pointers to manage the defect processing table in the computer readable medium.

19. The disc drive of claim 18, wherein the pointers comprise a defect pointer, a replace pointer and a process pointer.

20. The disc drive of claim 19, wherein the defect pointer indicates that a reading of the defect is finished, the replace pointer indicates that a reading of a replacement is finished, and the process pointer indicates that a transfer of the replacement is done for a reading operation of the disc.

21. The disc drive of claim 19, wherein the defect pointer indicates that the writing of a defect is finished, the replace pointer indicates that a location of a replacement for the defect is obtained, and the process pointer indicates that the writing of the replacement is finished for a recording operation of the disc.
